(19) United States
(12) Patent Application Publication
(10) Pub. No.: US 2005/0151259 A1
(43) Pub. Date: Jul. 14, 2005

(54) Semiconductor device and manufacturing method thereof

(76) Inventors: Naohiro Hosoda, Hitachinaka (JP); Kenji Kanamitsu, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/028,296

(22) Filed: Jan. 4, 2005

(30) Foreign Application Priority Data
Jan. 9, 2004 (JP) 2004-004509

(51) Int. Cl. H01L 23/48

(52) U.S. Cl. 257/758

(57) ABSTRACT

A silicon-rich oxide (SRO) film is arranged over an uppermost third-level wiring in a semiconductor device. Then, a silicon oxide film and a silicon nitride film lying over the third-level wiring are dry-etched to expose part of the third-level wiring to thereby form a bonding pad and to form an opening over the fuse. In this procedure, the SRO film serves as an etch stopper. This optimizes the thickness of the dielectric films lying over the fuse.

### CROSS-REFERENCE TO RELATED APPLICATION

The present application claims priority from Japanese Patent Application No. 2004-004509, filed on Jan. 9, 2004, the content of which is hereby incorporated by reference into this application.

### BACKGROUND OF THE INVENTION

The present invention relates in general to techniques to be performed on semiconductor devices and to methods of manufacture thereof. More specifically, it relates to techniques which give better control over etching of dielectric films arranged over a semiconductor substrate.

Japanese Unexamined Patent Publication No. 2001-332510 (patent document 1) discloses a technique for reducing damage and erosion inflicted upon a semiconductor substrate by reducing overetching of the semiconductor substrate even in the case of a contact hole having a large aspect ratio. Such a contact hole typically is formed by dry-etching a dielectric film that is formed over the semiconductor substrate, to thereby expose the semiconductor substrate.

In the manufacture of a semiconductor device according to this technique, a thin Si-rich dielectric film and a thick interlayer dielectric film comprising boron-doped phospho-silicate glass (BPSG) are sequentially formed on a semiconductor substrate bearing a diffusion layer, a photoresist film is formed as a mask, and the interlayer dielectric film and the Si-rich dielectric film are dry-etched using the photoresist film as a mask. A contact hole extending to the diffusion layer is thus formed. In this procedure, etching is once stopped at the surface of the Si-rich dielectric film by controlling the composition of the etching gas. The Si-rich dielectric film is then etched using another etching gas having a different composition.

The Si-rich dielectric film is a dielectric film having a silicon content (SiO, wherein 1≦x≦2) larger than that of a regular silicon oxide film, and it is prepared, for example, by plasma chemical vapor deposition (plasma CVD) using a 2:1 gaseous mixture of SiH₄ and O₂.

Japanese Unexamined Patent Publication No. 2001-85523 (patent document 2) discloses a technique for reducing extra process steps in the formation of a dual damascene structure on a semiconductor substrate.

The process for forming a dual damascene structure as disclosed in the patent document 2 comprises the steps of (a) forming a stacked layer comprising a first dielectric layer, a second dielectric layer and an etch-stop layer, (b) forming a first opening in one of the fist dielectric layer and the second dielectric layer, and (c) forming a second opening in at least two of the first dielectric layer, the second dielectric layer and the etch-stop layer, which second opening is smaller than the first opening and is formed at least at part of the base.

The first dielectric layer and the second dielectric layer each comprise a silicon oxide dielectric film, such as a boron-doped phospho-silicate glass (BPSG) film and a spin-on-glass (SOG) film. The etch-stop layer comprises a material exhibiting an etching resistance greater than that of the second dielectric layer with respect to selective etching. Examples of the material are Ta (tantalum), TaN (tantalum nitride), silicon nitride, silicon-rich oxide and multi-layer silicon oxide dielectrics.

Japanese Unexamined Patent Publication No. 2000-260871 (patent document 3) discloses a technique for solving problems in the formation of contact holes having different depths over a semiconductor substrate.

The method of manufacturing a semiconductor device as disclosed in patent document 3 comprises the steps of forming a first dielectric film over an underlayer circuit pattern having steps and being arranged on a semiconductor substrate, forming a second dielectric film on the first dielectric film, planarizing a surface of the second dielectric film, and forming plural contact holes having different depths and extending through the first and second dielectric films to the underlayer circuit pattern. The first dielectric film and the second dielectric film have different etching rates under the same etching condition. The first dielectric film serves as a stopper film against chemical and mechanical polishing (CMP) for planarizing the surface of the second dielectric film.

### SUMMARY OF THE INVENTION

In semiconductor memory devices, such as flash memories and DRAMs, a failed memory cell is switched to a redundant memory cell in order to avoid or remedy a defect. The switching is carried out by forming a fuse in part of a circuit and blowing the fuse, typically by the action of laser light.

Such a fuse is generally formed simultaneously with the formation of wiring arranged over a memory element on a semiconductor substrate. Upon completion of a wafer process, the top of a wiring layer, such as the fuse, is covered by a dielectric film. After intensive investigations, however, the present inventors have found for the first time that the following problems are inherent in the conventional techniques.

Specifically, if the dielectric film covering the fuse is excessively thick, the fuse cannot be blown due to insufficient energy, even when laser light is applied to the fuse from above. In general, therefore, to solve this problem, the surface protective film (dielectric film) lying over the fuse is also etched to reduce the thickness of the dielectric film lying over the fuse in a final step of the wafer process, in which the surface protective film (dielectric film) covering an uppermost-level wiring is etched to expose part of the uppermost-level of wiring to form a bonding pad. In contrast, an excessively thin dielectric film lying over the fuse may invite corrosion of the fuse, since such a thin dielectric film may allow water and other contaminants to penetrate the dielectric film lying over the fuse and reach the fuse. Thus, the control of the thickness of the dielectric film covering the fuse is a key factor affecting the yield and reliability of the resulting semiconductor device.

In the formation of a through hole for connecting upper-level and lower-level wirings by etching an interlayer dielectric film, misregistration in relative positions of the lower wiring and the through hole may occur due to misregistration of a photomask. This misregistration problem is becoming increasingly serious, since the wiring dimensions are being reduced more and more with an increase in the packing densities of semiconductor devices.

More specifically, a dielectric film covering a wiring lying under the lower-level wiring, the semiconductor element and the semiconductor substrate also will be overetched if the interlayer dielectric film is etched while the lower-level wiring and the through hole stay relatively misregistered. This may cause a shorting of a metal plug embedded in the through hole with the semiconductor element and/or the semiconductor substrate.

Accordingly, an object of the present invention is to provide a technique for optimizing the thickness of a dielectric film lying over a fuse by providing better control over etching of the dielectric film arranged over a semiconductor substrate.

Another object of the present invention is to provide a technique for preventing overetching of a dielectric film lying under a lower-level wiring even when a through hole for connecting upper-level and lower-level wirings is formed by etching an interlayer dielectric film while the lower-level wiring and the through hole stay relatively misregistered.

The present invention typically provides the following features and advantages.

The present invention provides, in a first aspect, a semiconductor device including a semiconductor substrate and multi-level wirings arranged over the semiconductor substrate with the interposition of an interlayer dielectric film, in which a first dielectric film comprising at least a silicon oxide film and a silicon-rich oxide film is arranged over an uppermost-level wiring, a bonding pad is arranged in place of part of the first dielectric film, and a fuse is arranged in a wiring layer lying under the uppermost level of wiring.

The present invention provides, in a second aspect, a semiconductor device including a semiconductor substrate, a first dielectric film arranged over the semiconductor substrate, a silicon-rich oxide film arranged over the semiconductor substrate via the first dielectric film, a first wiring arranged over the silicon-rich oxide film, an interlayer dielectric film arranged over the first wiring and comprising a silicon oxide film, and a second wiring arranged over the interlayer dielectric film, in which the first wiring and the second wiring are electrically connected with each other via a through hole arranged in the interlayer dielectric film.

The present invention further provides, in a third aspect, a method of manufacturing a semiconductor device, including the steps of:
(a) forming multi-level wirings over a semiconductor substrate with the interposition of an interlayer dielectric film;
(b) forming a fuse over the semiconductor substrate before the step of forming an uppermost-level wiring of the multi-level wirings;
(c) forming a first dielectric film comprising a silicon oxide film and a silicon-rich oxide film over the uppermost-level wiring; and
(d) etching the first dielectric film to expose part of the uppermost-level wiring to thereby form a bonding pad and an opening, the opening lying over the fuse.

In addition and advantageously, the present invention provides, in a fourth aspect, a method of manufacturing a semiconductor device, including the steps of:
(a) forming a first dielectric film over a semiconductor substrate, and forming a silicon-rich oxide film over the first dielectric film;
(b) forming a first wiring over the silicon-rich oxide film, and forming an interlayer dielectric film over the first wiring, the interlayer dielectric film comprising a silicon oxide film;
(c) etching the interlayer dielectric film to thereby form a through hole extending to the first wiring; and
(d) forming a second wiring over the interlayer dielectric film after etching to thereby electrically connect the second wiring with the first wiring via the through hole.

Typical advantages of the present invention are as follows.

The present invention can give better control over the etching of dielectric films arranged over a semiconductor substrate. In addition, the present invention can improve the yield and reliability of semiconductor devices.

### BRIEF DESCRIPTION OF THE DRAWINGS

FIGS. 1, 2, 3, 5, 6, 7, 8 and 10 are sectional views of a principal part of a semiconductor substrate, which sequentially illustrate steps in a method of manufacturing a semiconductor device representing an embodiment of the present invention;

FIG. 4 is a plan view illustrating the location of fuses and metal plugs arranged on both sides of each fuse;

FIG. 9 is a plan view illustrating the location of the fuses and an opening arranged over the fuses;

FIG. 11 is a plan view illustrating the location of an uppermost-level wiring and a bonding pad formed in part of the uppermost-level wiring;

FIGS. 12, 13, 14, 15, and 16 are sectional views of a principal part of a semiconductor substrate, which sequentially illustrate steps in a method of manufacturing a semiconductor device representing another embodiment of the present invention;

FIG. 17 is a sectional view of a principal part of a semiconductor substrate and illustrates a step in a method of manufacturing a semiconductor device representing still another embodiment of the present invention; and

FIG. 18 is a timing diagram illustrating an exemplified sequence for forming a silicon-rich oxide film and a silicon oxide film when the silicon-rich oxide film is formed as a silicon-rich silicon oxide film.

### DESCRIPTION OF THE PREFERRED EMBODIMENTS

The present invention will be described in further detail with reference to several embodiments, as illustrated in the attached drawings. In the drawings, the same members are indicated by the same reference numerals, and a repetitive description thereof will be omitted.

### First Embodiment

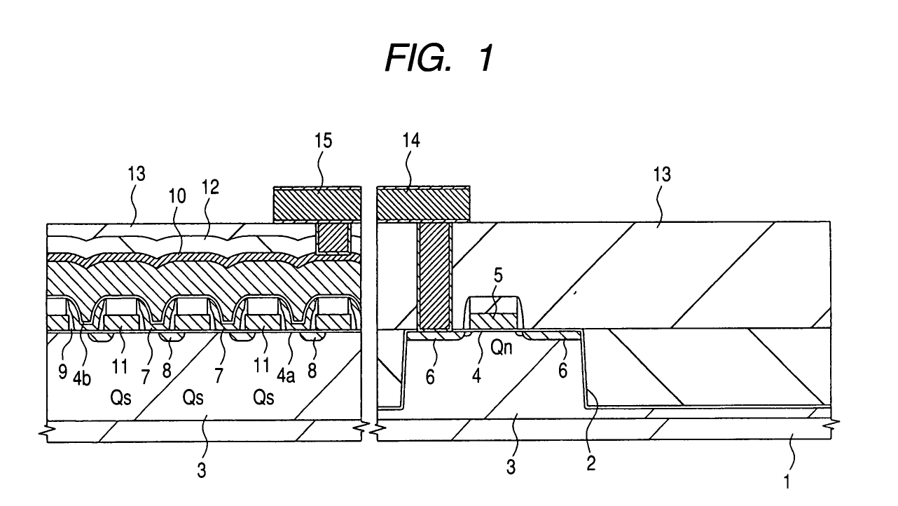

A method of manufacturing a semiconductor device will be sequentially described, step by step with reference to FIGS. 1 to 11. In the method, an opening is formed in a dielectric film arranged over a fuse. The left-hand parts in individual sectional views each represent a fuse-forming region and the right-hand parts thereof represent a bonding pad (hereinafter referred to as a “pad”) forming region.

With reference to FIG. 1, a device isolation trench 2, a p-type well 3, memory cells Qs serving as a flash memory, and an n-channel MISFET Qn serving as a peripheral circuit, for example, are initially formed on a semiconductor substrate (hereinafter referred to as a “substrate”) 1 according to conventional manufacturing processes. The substrate 1 comprises, for example, a p-type single-crystal silicon. Next, dielectric films, such as silicon oxide films 12 and 13, are formed over the memory cells Qs and the n-channel MISFET Qn by chemical vapor deposition (CVD). First-level wirings 14 and 15 are then formed on the silicon oxide film 13.

The memory cells Qs, serving as the flash memory, each comprise, for example, an n-type semiconductor region 8 that is arranged in the p-type well 3, and three gates, i.e., a floating gate 7, a control gate 10 and a selector gate 11. The floating gate 7 is arranged between two adjacent selector gates 11. The floating gate 7 and the p-type well 3 are isolated from each other by the action of a dielectric film, such as a first gate oxide film 4a. Likewise, the floating gate 7 and the selector gate 11 are isolated from each other by the action of an interlayer dielectric film, such as a silicon oxide film 9, and the floating gate 7 and the control gate 10 are isolated from each other by the action of a dielectric film, such as a second gate oxide film 4b. The control gate 10 extends in a longitudinal direction (line-writing direction; lateral direction in the figure) and constitutes a word line. The selector gate 11 extends column-wise, i.e., in a transverse direction perpendicular to the word line. The n-type semiconductor region 8 extends column-wise, i.e., in a transverse direction perpendicular to the word line and serves as a local bit line.

The n-channel MISFET Qn constituting the peripheral circuit of the flash memory comprises a gate oxide film 4, an n-type semiconductor region 6 and a gate electrode 5. The peripheral circuit comprises the n-channel MISFET Qn and a p-channel MISFET (not shown).

The surface of the silicon oxide film 13 covering the memory cells Qs and the n-channel MISFET Qn is planarized by chemical mechanical polishing (CMP). The first-level wiring 14 is electrically connected to the n-channel MISFET Qn, and the first-level wiring 15 is electrically connected to the memory cells Qs. The first-level wirings 14 and 15 each comprise a metal film or metal nitride film, such as a tungsten (W) film, titanium (Ti) film, titanium nitride (TiN) film, an aluminum alloy film, or a multilayer film comprising a Ti film and a TiN film.

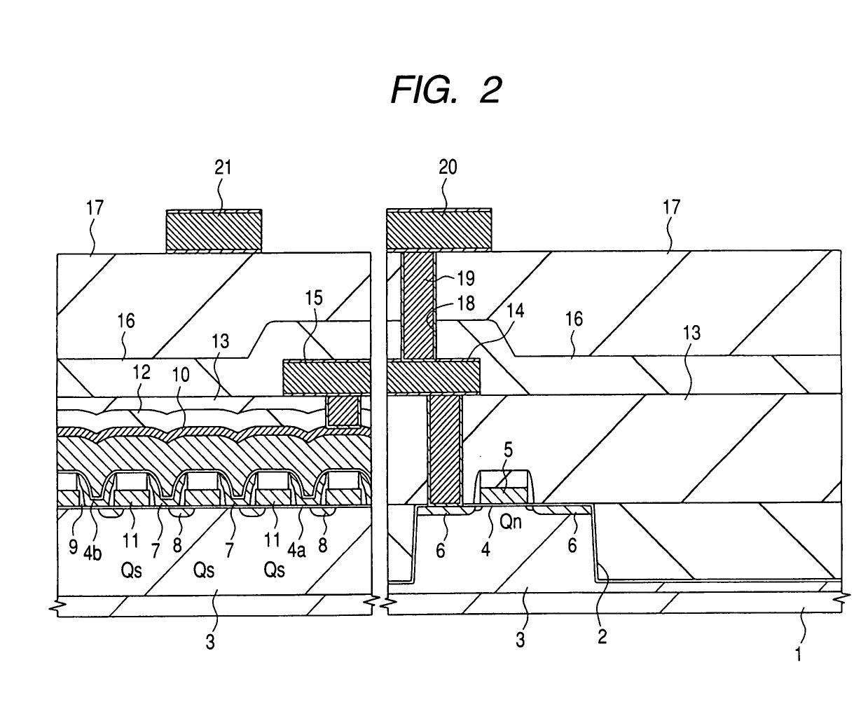

Next, with reference to FIG. 2, silicon oxide films 16 and 17 are deposited over the first-level wirings 14 and 15 by CVD. The surface of the silicon oxide film 17 is planarized by chemical mechanical polishing. A through hole 18 is then formed in the silicon oxide films 16 and 17, followed by charging of a metal plug 19 inside the through hole 18. A second-level wiring 20 and a fuse 21 are then formed over the silicon oxide film 17. The metal plug 19 serves to electrically connect the second-level wiring 20 with the first-level wiring 14 and comprises a Ti film, a TiN film and a W film. The second-level wiring 20 and the fuse 21 comprise the same material as the first-level wirings 14 and 15. The fuse 21 serves as a switch for switching a failed memory cell Qs to a redundant memory cell. By blowing the fuse 21, typically by the action of laser light, the failed memory cell Qs is switched to the redundant memory cell.

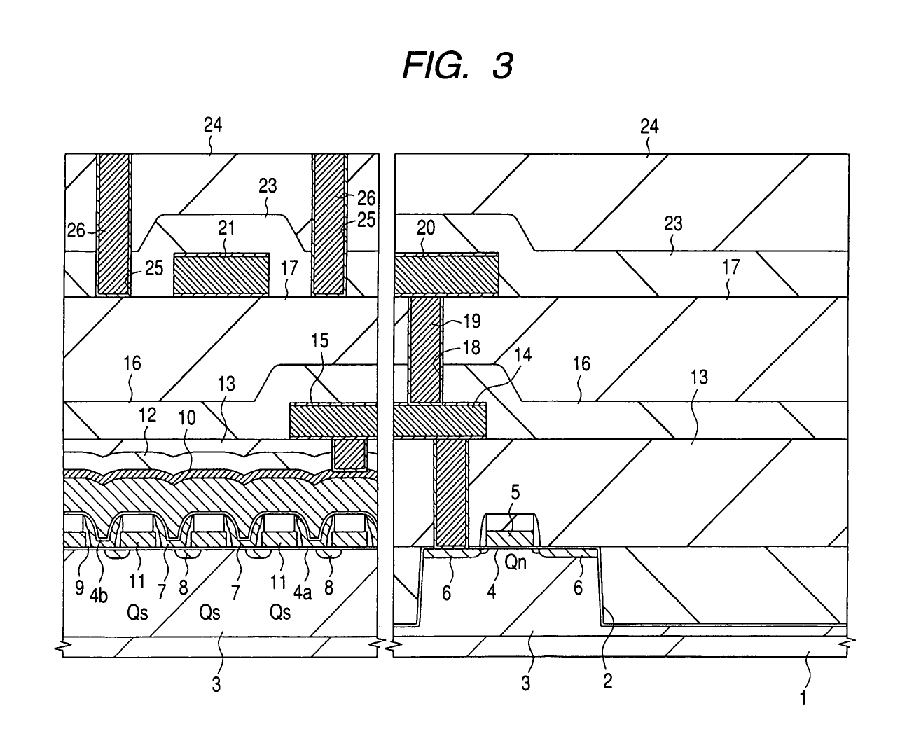

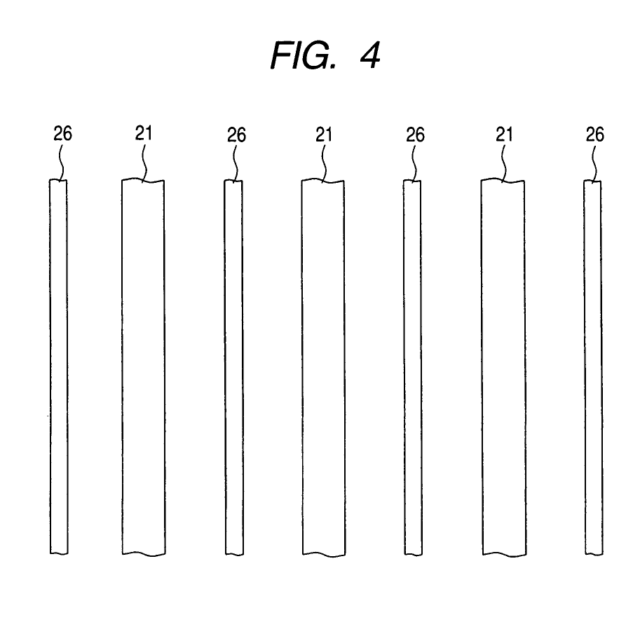

Next, with reference to FIG. 3, silicon oxide films 23 and 24 are formed over the second-level wiring 20 and the fuse 21 by CVD. The surface of the silicon oxide film 24 is planarized by chemical mechanical polishing. Through holes 25 are formed in the silicon oxide films 23 and 24 on both sides of the fuse 21, and metal plugs 26 are charged inside the through holes 25. The metal plugs 26 serve as a barrier layer for preventing corrosion of the fuse 21. Such corrosion is caused, for example, by moisture that has permeated from an opening which will be formed over the fuse 21 in a later step. The metal plugs 26 are formed from the same materials (Ti film, TiN film and W film) as the underlying metal plug 19. With reference to FIG. 4, it can be seen that the metal plugs 26 are arranged in parallel with the fuse 21.

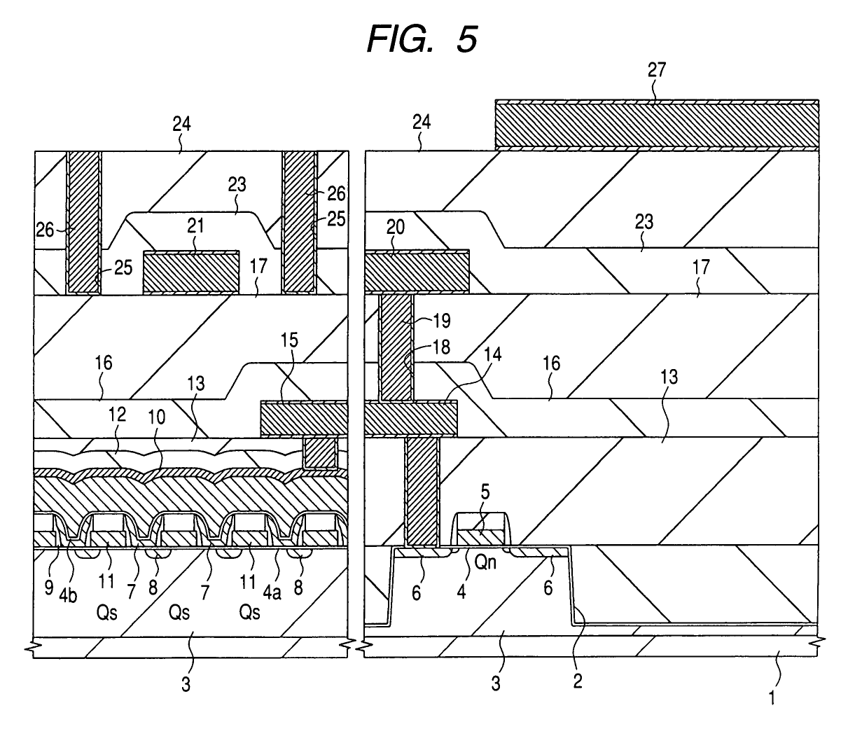

With reference to FIG. 5, a third-level wiring 27 is formed over the silicon oxide film 24. The third-level wiring 27 serves as an uppermost wiring of the flash memory and is formed from the same materials as the underlying wirings (the first-level wirings 14 and 15, and the second-level wiring 20).

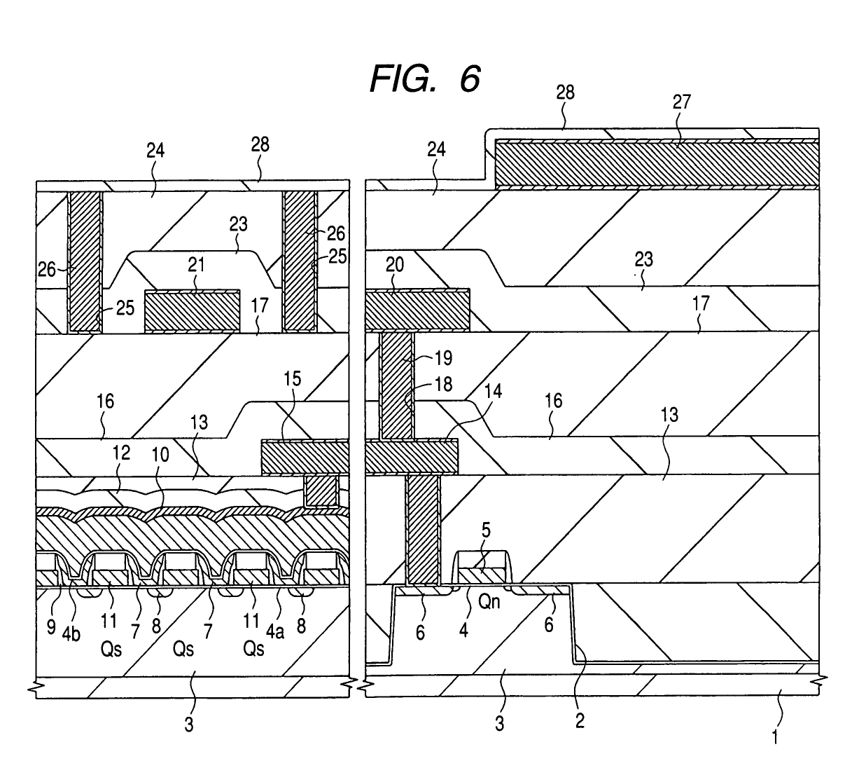

With reference to FIG. 6, a silicon-rich oxide (hereinafter referred to as SRO) film 28 is deposited over the third-level wiring 27. The SRO film 28 has a Si content greater than that of a regular silicon oxide film having a compositional ratio of Si to oxygen of 1:2. Namely, the underlying SRO film 28 has a larger content of silicon than a to be provided overlying dielectric film 29 (silicon oxide film 29). The SRO film 28 is formed by plasma CVD using the same gases, such as SiH₄ gas and O₂ gas, as in the formation of a regular silicon oxide film. In this case, the ratio of SiH₄ gas to O₂ gas is set higher than in the formation of a regular silicon oxide film. The thickness of the SRO film 28 is set, for example, at about 70 nm.

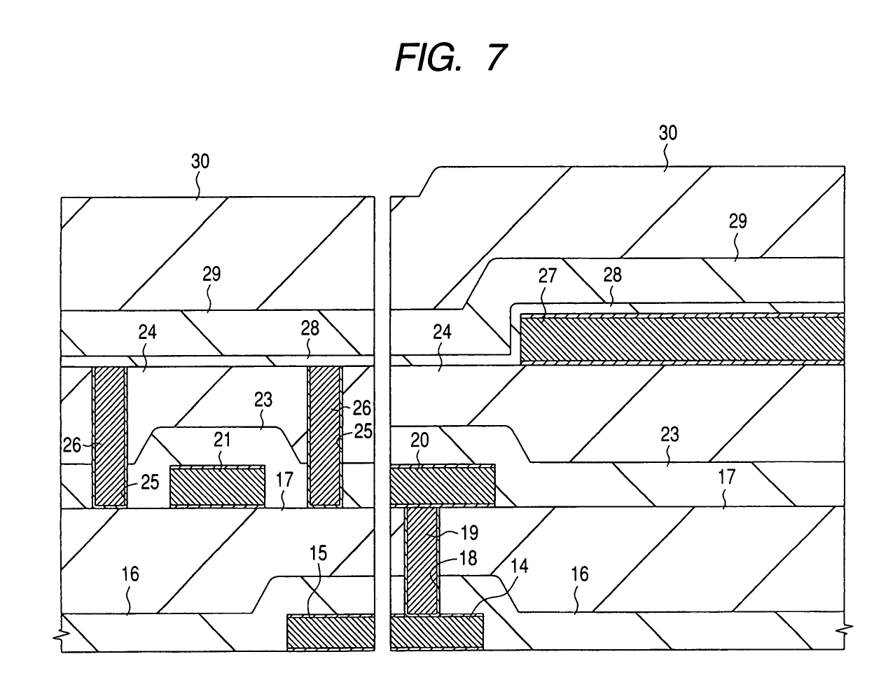

With reference to FIG. 7, the silicon oxide film 29 is then formed on the SRO film 28 by plasma CVD, and a silicon nitride film 30 is formed on the silicon oxide film 29 by plasma CVD. The thicknesses of the silicon oxide film 29 and the silicon nitride film 30 are set, for example, at about 900 nm and about 700 nm, respectively.

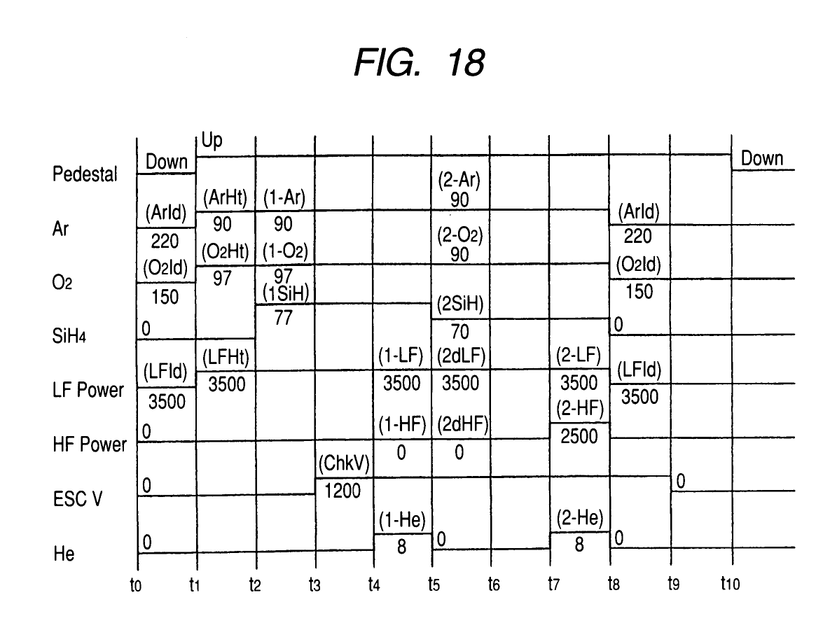

FIG. 18 illustrates an example of a film-forming sequence of the SRO film 28 and the silicon oxide film 29, when the SRO film 28 is formed as a silicon-rich silicon oxide film. The numerals in the sequences of the gases each represent a supplied amount of a gas in sccm (cm³/min). The numerals in the sequences of the upper electrode HF Power and lower electrode LF power each represent a high-frequency power in W.

The SRO film 28 herein may be formed, for example, by plasma CVD using a silane gas. The plasma CVD apparatus used for this purpose may be, for example, a parallel plate reactor. As a treatment gas, for example, a gaseous mixture containing a silane gas, such as monosilane (SiH₄), oxygen gas (O₂ gas) and a diluent gas, such as argon (Ar) gas, may be used. Another silane gas, such as disilane (Si₂H₆) gas or tetraethoxysilane (TEOS) gas, can be used instead of the monosilane gas. An oxygen-containing gas, such as nitrous oxide (N₂O) gas or ozone (O₃) gas, can be used instead of the oxygen gas. A time period between t0 and t1 is an idling time; a time period between t2 and t5 represents a film-forming time of the SRO film 28; and a time period between t5 and t8 represents a film-forming time of the silicon oxide film 29. Heating of the wafer 1W and supply of argon and oxygen to a reaction chamber start at the time t1. The supply of monosilane starts at the time t2. For forming the SRO film 28 as a silicon-rich film, the flow rate of monosilane in the film-forming of the SRO film 28 is set to be greater than that of the silicon oxide film 29. The flow rates of the monosilane gas, oxygen gas and argon gas in film-formation of the SRO film 28 are set, for example, at about 77 sccm (i.e., 77 cm³/min), about 97 sccm and about 90 sccm, respectively. The flow rates of the monosilane gas, oxygen gas and argon gas in film-formation of the silicon oxide film 29 are set, for example, at about 70 sccm, about 90 sccm, and about 90 sccm, respectively.

When the underlying SRO film 28 is formed as a silicon oxide film that is richer in silicon than the overlying silicon oxide film 29, the SRO film 28 and the silicon oxide film 29 can be formed in a reaction chamber of one plasma CVD apparatus so that the former has a silicon content higher than that of the latter. This shortens the film-forming time period. In addition, the SRO film 28 and the silicon oxide film 29 can be formed continuously and stably with less contamination by foreign matter. This improves the reliability of the film-forming process.

When such a thick dielectric film, comprising the silicon oxide film 29 and the silicon nitride film 30, is formed over the SRO film 28, the thickness of the dielectric film varies between a region over the third-level wiring 27 and a region under which the third-level wiring 27 is not formed, such as a region over the fuse 21. Specifically, the dielectric film lying over the fuse 21 comprises at least a silicon oxide film and an SRO film. In addition, the SRO film is formed as the lowermost layer of the dielectric film lying over the fuse 21 and can thereby serve as an etching stopper during etching of the silicon oxide film.

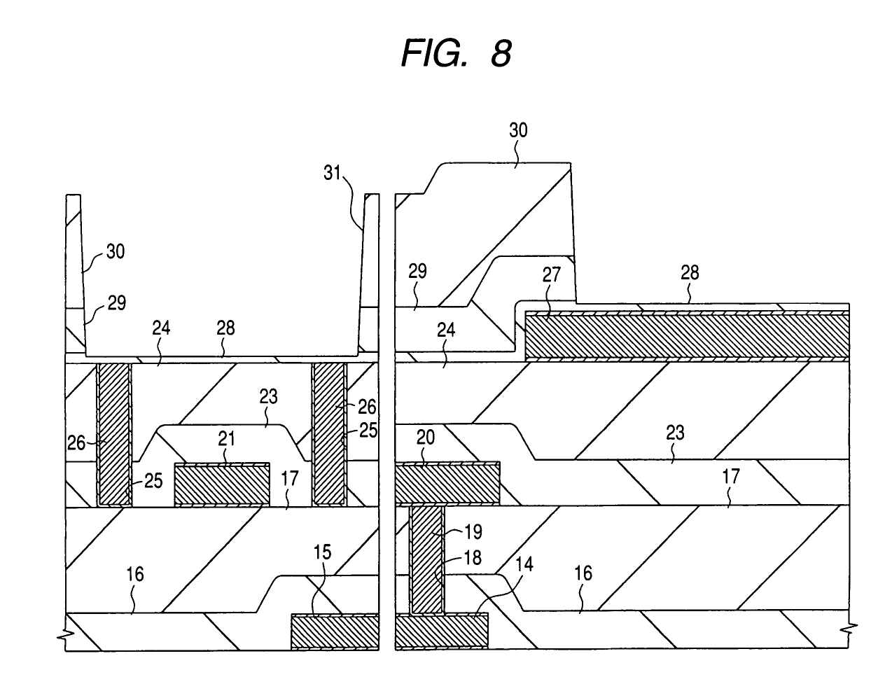

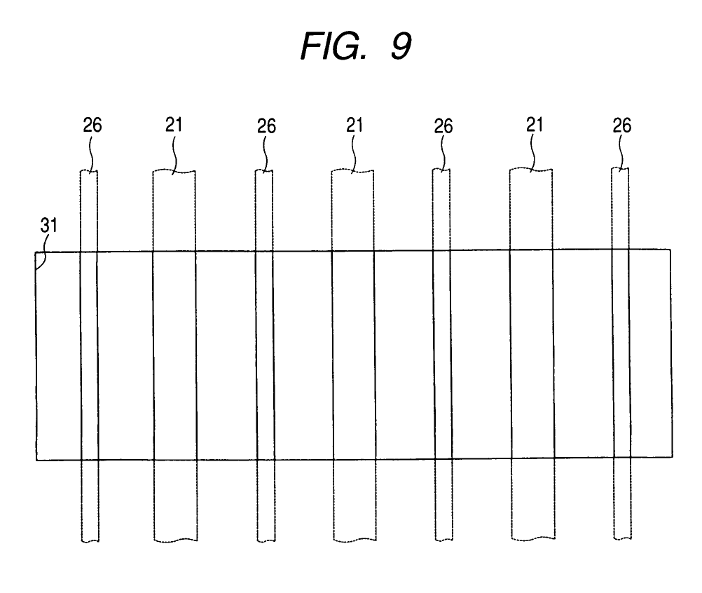

With reference to FIG. 8, an opening is formed over the fuse 21 to thereby set the thickness of the dielectric film lying over the fuse 21 at a desired level. FIG. 9 illustrates an example of the planar pattern (location) of the fuse 21 and the opening 31 formed over the fuse 21.

The opening 31 is formed by dry-etching the dielectric film comprising the silicon oxide film 29 and the silicon nitride film 30 in a region over the fuse 21 using a photoresist film (not shown) as a mask. In this procedure, the dielectric film comprising the silicon oxide film 29 and the silicon nitride film 30 in a region over the third-level wiring 27 is also dry etched in order to expose part of the third-level wiring 27 to thereby form the pad.

The SRO film 28 serves as an etching stopper during dry etching of the silicon oxide film 29, subsequent to etching of the silicon nitride film 30, since the silicon oxide film 29 and the underlying SRO film 28 have different etching rates. Specifically, the etching is stopped at the surface of the SRO film 28 in regions over the third-level wiring 27 and over the fuse 21, even if the thickness of the dielectric film comprising the silicon oxide film 29 and the silicon nitride film 30 varies between regions over the third-level wiring 27 and over the fuse 21.

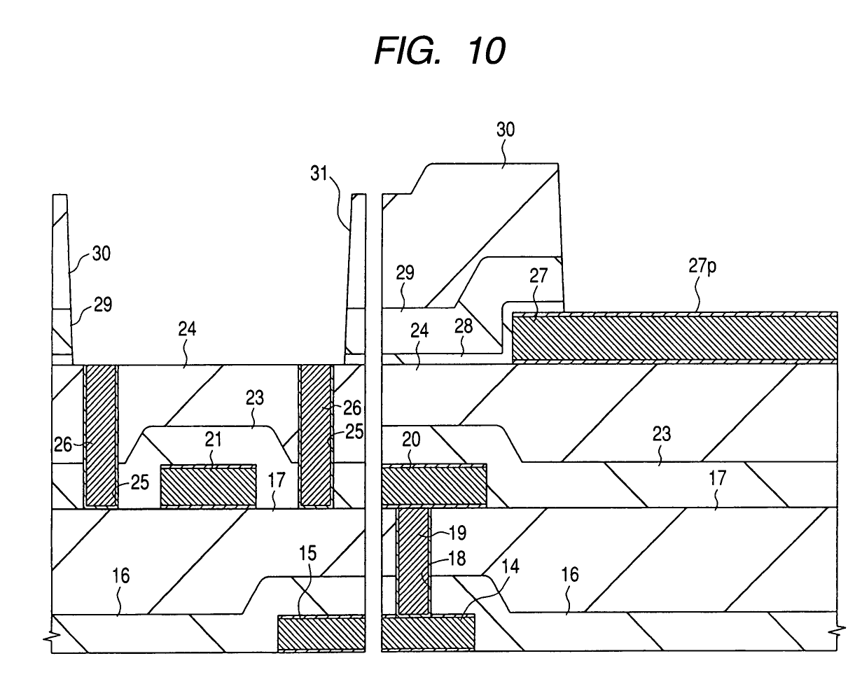

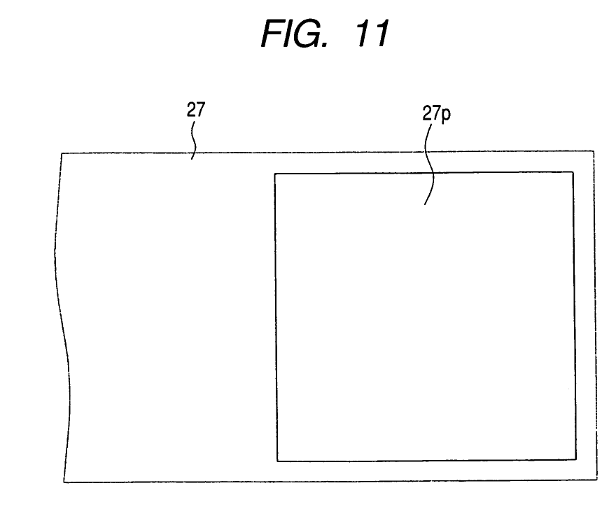

Next, as seen with reference to FIG. 10, the SRO film 28 at the bottom of the opening 31 (through hole 31) and in a region over the third-level wiring 27 is removed by changing the etching condition. This allows part of the third-level wiring 27 to be exposed to thereby form a pad 27p and specifies the thickness of the dielectric film lying over the fuse 21. In this procedure, the silicon oxide film 24 and the third-level wiring 27 lying under the SRO film 28 are hardly etched, since these films have different etching rates from that of the SRO film 28. FIG. 11 illustrates an example of the planar pattern (location) of the third-level wiring 27 and the pad 27b formed by exposing part of the third-level wiring 27. Au wires and components are bonded on the surface of the pad 27p in a subsequent step.

According to the present embodiment (First Embodiment), the SRO film 28, serving as an etch stopper, is arranged under the silicon oxide film 29. Then, the thick dielectric film comprising the silicon oxide film 29 and the silicon nitride film 30 is formed over the third-level wiring 27, serving as the uppermost-level wiring, and the dielectric film is dry-etched to thereby form the opening 31 and the pad 27p. This gives better control over the etching amount of the silicon oxide film 29 even if the dielectric film comprising the silicon oxide film 29 and the silicon nitride film 30 has a varying thickness between a region over the third-level wiring 27 and a region over the fuse 21. The fuse herein serves as the second-level wiring. Thus, overetching of the underlying dielectric films can be prevented upon formation of the opening 31, and the thickness of the dielectric film lying over the fuse 21 can be optimized. This improves the yield and the reliability of semiconductor devices such as flash memories.

The SRO film 28 is arranged under the silicon oxide film 29 in the present embodiment, but it may be arranged adjacent to the silicon oxide film 29, i.e., between the silicon oxide film 29 and the silicon nitride film 30. Alternatively, the SRO film 28 may be arranged inside the silicon oxide film 29 to constitute a multilayer structure comprising the silicon oxide film 29, the SRO film 28 and the silicon oxide film 29 in this order. In any case, the same advantages as the case where the SRO film 28 is formed below the silicon oxide film 29 can be obtained.

### Second Embodiment

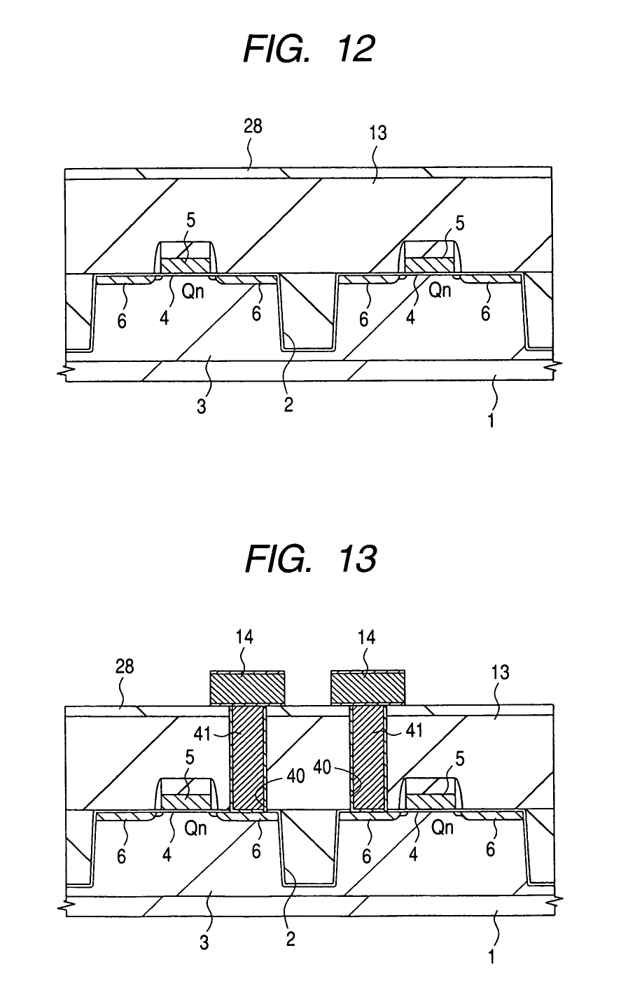

Another method of manufacturing a semiconductor device will be described with reference to FIGS. 12 to 16. In this method, a through hole is formed in a dielectric film over wirings.

Initially, as seen with reference to FIG. 12, a device isolation trench 2, a p-type well 3, an n-channel MISFET Qn and other components are formed on a substrate 1 according to conventional manufacturing procedures. A dielectric film, such as a silicon oxide film 13, is formed on the n-channel MISFET Qn by CVD, a surface of the silicon oxide film 13 is planarized by chemical mechanical polishing, and an SRO film 28 is formed over the silicon oxide film 13. The thickness of the SRO film 28 is set, for example, at about 70 nm. The SRO film 28 has the same configuration and is formed by the same manufacturing procedure as used in the First Embodiment.

With reference to FIG. 13, the SRO film 28 and the silicon oxide film 13 are dry-etched to form a contact hole 40, a metal plug 41 is charged inside the contact hole 40, and a first-level wiring 14 is formed over the SRO film 28 and is electrically connected to the n-channel MISFET Qn via the metal plug 41.

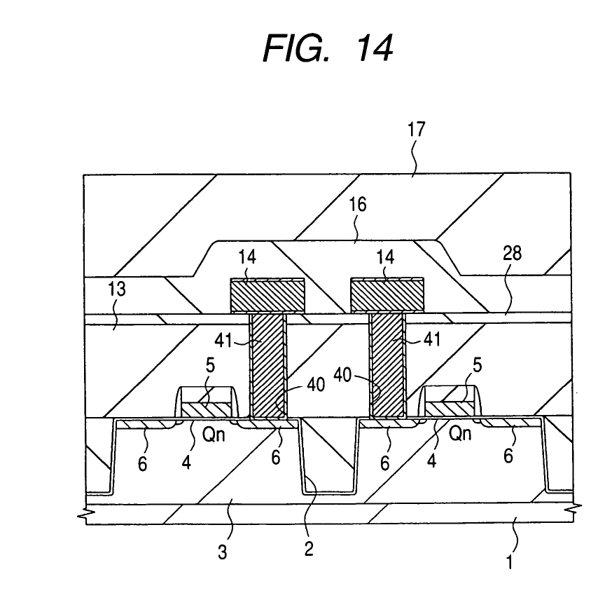

With reference to FIG. 14, dielectric films 16 and 17 (silicon oxide films 16 and 17) are formed over the first-level wiring 14 by CVD, and the surface of the silicon oxide film 17 is planarized by chemical mechanical polishing. The SRO film 28 and the dielectric film 16 (silicon oxide film 16) can be continuously formed in a reaction chamber of one plasma CVD apparatus, as in the case of the First Embodiment. Thus, the time for film formation can be shortened with less contamination by foreign matter. This improves the reliability of the film-forming process.

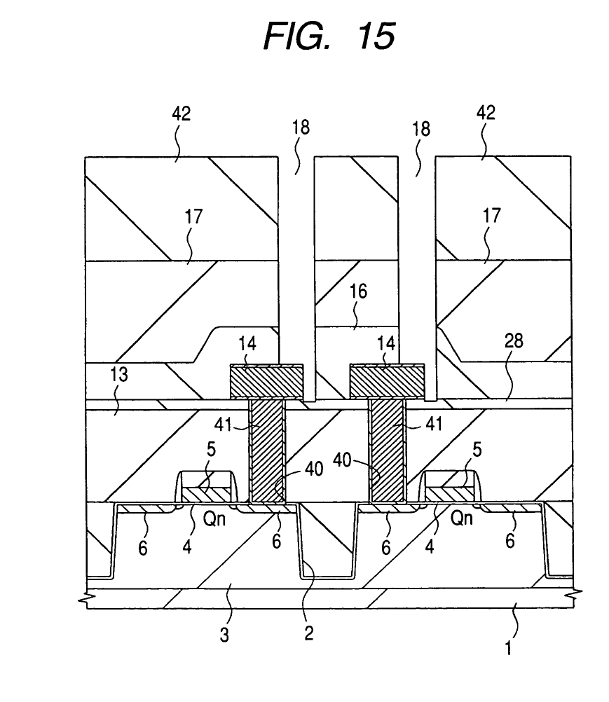

With reference to FIG. 15, a photoresist film 42 is formed over the silicon oxide film 17, and the silicon oxide films 17 and 16 are dry-etched using the photoresist film 42 as a mask to thereby form a through hole 18 over the first-level wiring 14. In this procedure, the relative position between the first-level wiring 14 and the through hole 18 may be misregistered due to misregistration of the photomask. According to the present embodiment, however, etching of the silicon oxide film 13 lying under the through hole 18 is prevented even upon such misregistration, since the silicon oxide film 16 and the underlying SRO film 28 have different etching rates, and the SRO film 28 serves as an etching stopper. This prevents the through hole 18 from penetrating the silicon oxide film 13 and extending to the n-channel MISFET Qn and the substrate 1, which in turn prevents an electrical circuit between the n-channel MISFET Qn or the substrate 1 and a metal plug, which will be embedded inside the through hole 18 in a subsequent step.

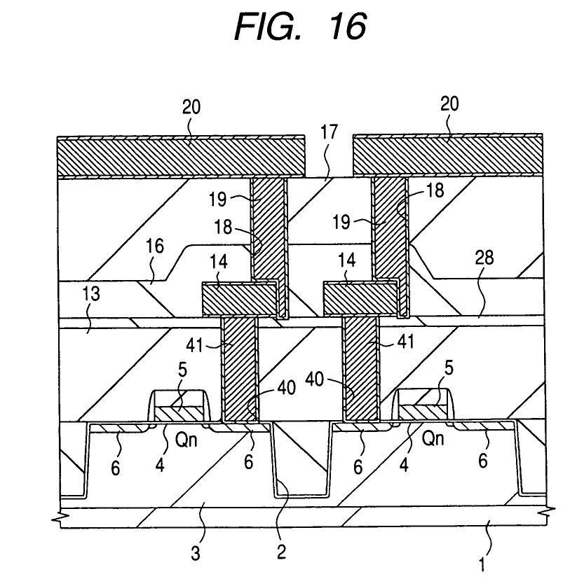

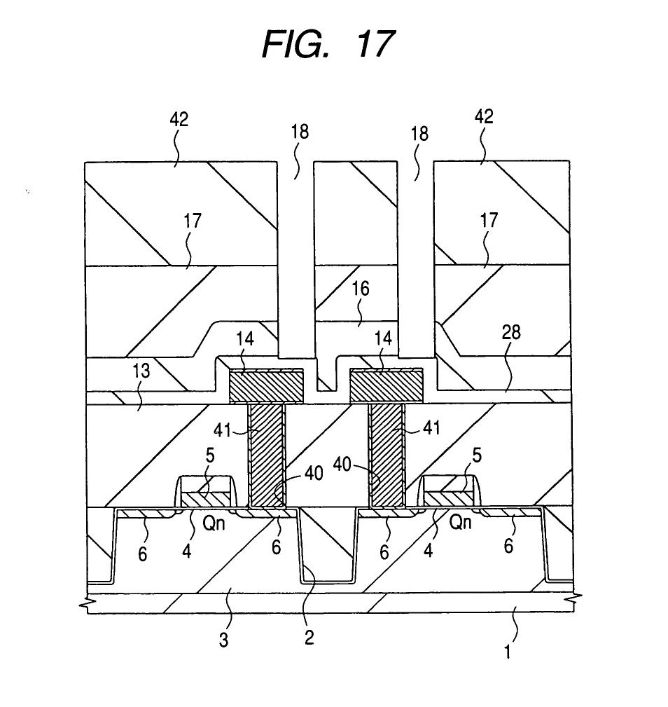

With reference to FIG. 16, a metal plug 19 is charged into the through hole 18, and a second-level wiring 20 is formed over the silicon oxide film 17. The metal plug 19 is formed by the same procedure as used in the First Embodiment.

The present embodiment can avoid defects caused by the relative misregistration between the wiring and a through hole and improve the yield and reliability of the semiconductor device. In addition, the wiring dimensions and, in turn, the chip area can be reduced.

Typical advantages of the present invention will be briefly described below.

Dielectric films arranged on a semiconductor substrate can be etched more precisely by using a silicon-rich oxide film as an etching stopper during etching of the silicon oxide films (dielectric films). This gives better control over the etching amount of the silicon oxide films arranged over the semiconductor substrate, which in turn optimizes the thickness of the dielectric film lying over the fuse.

The use of a silicon-rich oxide film as an etching stopper during etching of the silicon oxide film gives better control over the etching amount of the silicon oxide films arranged over the semiconductor substrate. This prevents dielectric films lying under the lower-level wiring during etching of the interlayer dielectric film to form a through hole which connects the upper-level wiring with the lower-level wiring.

In the above-mentioned embodiments, the SRO film 28 is arranged under the first-level wiring 14. It is also acceptable if the SRO film 28 and the silicon oxide films 16 and 17 are formed over the first-level wiring 14, the SRO film 28 is allowed to serve as an etching stopper during dry etching of the silicon oxide films 16 and 17, and then the SRO film 28 is dry-etched to expose the first-level wiring 14. In this case, the etching of the silicon oxide film 13 can be surely prevented by setting the thickness of the SRO film 28 in a region in contact with a side wall of the first-level wiring 14 (thickness in a direction in parallel with the principal plane of the substrate 1) greater than the maximum misregistration of the photomask.

The SRO film 28 may be arranged inside the silicon oxide film 16, between the silicon oxide film 16 and the silicon oxide film 17, or inside the silicon oxide film 17, and it is preferably arranged near to the first-level wiring 14.

In the above-mentioned embodiments, the second-level wiring 20 and the first-level wiring 14 are connected via the metal plug 19 embedded inside the through hole 18. It is also acceptable if the second-level wiring 20 is arranged over the silicon oxide film 17 and inside the through hole 18 to thereby directly connect the second-level wiring 20 and the first-level wiring 14.

Although the invention made by the present inventors has been described above in specific terms with reference to preferred embodiments thereof, the invention is not confined to the disclosed embodiments, but can be modified in various ways without deviating from its true spirit and scope.

The SRO film having a silicon content greater than a regular silicon oxide film is used as an etching stopper upon etching of the silicon oxide films. Similar advantages can also be obtained by using a dielectric film having a modified etching rate as the etching stopper. The etching rate of such a silicon oxide film can be modified by adding at least one of nitrogen, fluorine and carbon atoms to a regular silicon oxide film.

The present invention can be applied to semiconductor devices of the type which use a fuse for remedying defects by switching a failed memory cell to a redundant memory cell.

1. A semiconductor device comprising: a semiconductor substrate; and multi-level wirings arranged over the semiconductor substrate with the interposition of an interlayer dielectric film,
wherein a first dielectric film comprising at least a silicon oxide film and a silicon-rich oxide film is arranged over an uppermost-level wiring,
wherein a bonding pad is arranged instead of part of the first dielectric film, and
wherein a fuse is arranged in a wiring level lying under the uppermost level of wiring.

2. The semiconductor device according to claim 1, further comprising an opening instead of part of the first dielectric film over the fuse.

3. The semiconductor device according to claim 1, wherein the fuse is covered with an interlayer dielectric film comprising a silicon oxide film.

4. The semiconductor device according to claim 1, wherein the silicon-rich oxide film constitutes a lowermost layer of the first dielectric film.

5. A semiconductor device comprising:
a semiconductor substrate;
a first dielectric film arranged over the semiconductor substrate;
a silicon-rich oxide film arranged over the first dielectric film;
a first wiring arranged over the silicon-rich oxide film;
an interlayer dielectric film being arranged over the first wiring and comprising a silicon oxide film; and
a second wiring arranged over the interlayer dielectric film,
wherein the first wiring and the second wiring are electrically connected with each other via a through hole arranged in the interlayer dielectric film.

6. The semiconductor device according to claim 5, wherein the first dielectric film comprises a silicon oxide film.

7. A semiconductor device comprising:
a semiconductor substrate;
a first dielectric film arranged over the semiconductor substrate;
a first wiring arranged over the first dielectric film;
an interlayer dielectric film being arranged over the first wiring and comprising at least a silicon oxide film and a silicon-rich oxide film; and
a second wiring arranged over the interlayer dielectric film,
wherein the first wiring and the second wiring are electrically connected with each other via a through hole arranged in the interlayer dielectric film.

8. The semiconductor device according to claim 7, wherein the silicon-rich oxide film constitutes a lowermost layer of the interlayer dielectric film.

9. The semiconductor device according to claim 7, wherein the first dielectric film comprises a silicon oxide film.

10. A method for manufacturing a semiconductor device, comprising the steps of:
(a) forming multi-level wirings over a semiconductor substrate with the interposition of an interlayer dielectric film;
(b) forming a fuse over the semiconductor substrate before the step of forming an uppermost-level wiring of the multi-level wirings;
(c) forming a first dielectric film comprising a silicon oxide film and a silicon-rich oxide film over the uppermost-level wiring; and
(d) etching the first dielectric film to expose part of the uppermost-level wiring to thereby form a bonding pad and an opening, the opening lying over the fuse.

11. The method according to claim 10, further comprising forming the silicon-rich oxide film as a lowermost layer of the first dielectric film.

12. The method according to claim 10, further comprising forming the fuse simultaneously with any of wirings lying under the uppermost-level wiring.

13. The method according to claim 10, wherein in the step (d), upon etching the first dielectric film, a condition of etching the silicon oxide film and a condition of etching the silicon-rich oxide film are different from each other.

14. A method for manufacturing a semiconductor device, comprising the steps of:
(a) forming a plurality of first-level wirings over a semiconductor substrate;
(b) forming a plurality of second-level wirings over the first level wirings via a first dielectric film;
(c) forming a second dielectric film over the second-level wirings; and
(d) selectively etching the second dielectric film to thereby form an opening over part of the second-level wirings and over part of the first-level wirings,
wherein the second dielectric film comprises at least two layers including an upper layer and a lower layer, and the lower layer has a silicon content higher than that of the upper layer.

15. The method according to claim 14, wherein part of the first-level wirings functions as a fuse.

16. The method according to claim 14, further comprising continuously forming the first dielectric film in one apparatus.

17. The method according to claim 14, wherein in the step (d), upon etching the second dielectric film, a condition of etching the under layer of the second dielectric film and a condition of etching the upper layer of the second dielectric film are different from each other.

18. A method for manufacturing a semiconductor device, comprising the steps of:
(a) forming a first dielectric film over a semiconductor substrate, and forming a silicon-rich oxide film over the first dielectric film;
(b) forming a first wiring over the silicon-rich oxide film, and forming an interlayer dielectric film over the first wiring, the interlayer dielectric film comprising a silicon oxide film;
(c) etching the interlayer dielectric film to thereby form a through hole extending to the first wiring; and
(d) forming a second wiring over the interlayer dielectric film after etching to thereby electrically connect the second wiring with the first wiring via the through hole.

19. The method according to claim 18, wherein the first dielectric film comprises a silicon oxide film.

20. A method for manufacturing a semiconductor device, comprising the steps of:
(a) forming a first dielectric film over a semiconductor substrate, and forming a first wiring over the first dielectric film;
(b) forming an interlayer dielectric film over the first wiring, the interlayer dielectric film comprising a silicon oxide film and a silicon-rich oxide film;
(c) etching the interlayer dielectric film to thereby form a through hole extending to the first wiring; and
(d) forming a second wiring over the interlayer dielectric film after etching to thereby electrically connect the second wiring with the first wiring via the through hole.

21. The method according to claim 20, further comprising forming the silicon-rich oxide film as a lowermost layer of the interlayer dielectric film.

22. The method according to claim 20, wherein the first dielectric film comprises a silicon oxide film.
